(19) United States
(12) Patent Application Publication
(10) Pub. No.: US 2025/0151546 A1
(43) Pub. Date: May 8, 2025

(54) DISPLAY DEVICE AND METHOD OF MANUFACTURING THE SAME

(71) Applicant: Samsung Display Co., Ltd., Yongin-Si (KR)

(72) Inventors: Youn Woong KANG, Yongin-si (KR); Sang Hyeon SONG, Yongin-si (KR); Si Joon SONG, Yongin-si (KR)

(21) Appl. No.: 18/745,789

(22) Filed: Jun. 17, 2024

(30) Foreign Application Priority Data
Nov. 6, 2023 (KR) 10-2023-0151911

(51) Int. Cl. H10K 59/131; H10K 59/12; H10K 59/40

(52) U.S. Cl. CPC H10K 59/131; H10K 59/1201; H10K 59/40

(57) ABSTRACT

A display device is disclosed that includes a first substrate, a first barrier insulating layer, a pad part, a second substrate, a first connection line, a flexible film, and a contact part. The first substrate includes an open part. The first barrier insulating layer is disposed on the first substrate and includes a first contact hole. The pad part is disposed on the first barrier insulating layer and inserted into the first contact hole. The second substrate is disposed on the pad part. The first connection line is disposed on the second substrate and connected to the pad part. The flexible film is partially inserted into the open part of the first substrate and includes a lead electrode spaced apart from the pad part in a plan view. The contact part electrically connects the pad part and the lead electrode to each other.

### CROSS-REFERENCE TO RELATED APPLICATION

This application claims priority from Korean Patent Application No. 10-2023-0151911 filed on Nov. 6, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device and a method of manufacturing the same.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions. The display devices may be flat panel display devices such as liquid crystal display devices, field emission display devices, or organic light emitting display devices. Among such flat panel display devices, a light emitting display device may display an image without a backlight unit providing light to a display panel because each of pixels of the display panel includes light emitting elements that may emit light by themselves.

### SUMMARY

Aspects of the present disclosure may provide a display device capable of easily connecting a lead electrode and a pad part to each other even when misalignment occurs in a process of aligning the lead electrode and the pad part with each other, and a method of manufacturing the same.

Aspects of the present disclosure also may provide a display device capable of reducing a manufacturing time and a manufacturing cost by minimizing an area of a non-display area and simplifying manufacturing processes, and a method of manufacturing the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an embodiment, a display device comprises a first substrate including an open part, a first barrier insulating layer disposed on the first substrate and including a first contact hole, a pad part disposed on the first barrier insulating layer and inserted into the first contact hole, a second substrate disposed on the pad part, a first connection line disposed on the second substrate and connected to the pad part, a flexible film partially inserted into the open part of the first substrate and including a lead electrode spaced apart from the pad part in a plan view, and a contact part electrically connecting the pad part and the lead electrode to each other.

The contact part may cover a lower surface of the lead electrode and a lower surface of the pad part.

The contact part may cover a lower surface of the first barrier insulating layer disposed between the lead electrode and the pad part.

The contact part may correspond to a conductive line connecting a center of the lead electrode protruding from the flexible film and a center of the pad part inserted into the first contact hole to each other.

The second substrate may include a second contact hole spaced apart from the first contact hole in the plan view, and the first connection line may be inserted into the second contact hole to be connected to the pad part.

The second substrate may include a second contact hole overlapping the first contact hole, and the first connection line may be inserted into the second contact hole to be connected to the pad part.

The display device may further comprise a gate insulating layer disposed on the second substrate, a second connection line disposed on the gate insulating layer and connected to the first connection line, and an interlayer insulating layer disposed at a layer between the second connection line and the first connection line.

The display device may further comprise a semiconductor region of a transistor disposed on the second substrate, a gate electrode of the transistor disposed on the gate insulating layer, and a connection electrode disposed on the interlayer insulating layer and electrically connected to the transistor. The first connection line may include the same material as the connection electrode and may be formed in the same process as the connection electrode. The second connection line may include the same material as the gate electrode of the transistor and may be formed in the same process as the gate electrode.

According to an embodiment, a display device comprises a first substrate including an open part, a first barrier insulating layer disposed on the first substrate and including a plurality of first contact holes, a plurality of pad parts disposed on the first barrier insulating layer and inserted into the plurality of first contact holes, respectively, a second substrate disposed on the plurality of pad parts, a plurality of first connection lines disposed on the second substrate and connected to the plurality of pad parts, respectively, a flexible film partially inserted into the open part of the first substrate and including a plurality of lead electrodes, a plurality of partition walls disposed between adjacent pad parts of the plurality of pad parts on a lower surface of the first barrier insulating layer, and contact parts connecting the pad parts and the lead electrodes to each other in a one-to-one manner between adjacent partition walls of the plurality of partition walls.

The lead electrode may be attached to a lower surface of the pad part through an adhesive member, and the contact part may cover a lower surface of the lead electrode and the lower surface of the pad part.

The partition wall may include an organic film made of an acrylic resin, an epoxy resin, a phenolic resin, a polyamide resin, or a polyimide resin.

According to an embodiment, a method of manufacturing a display device comprises providing a first substrate, forming a first barrier insulating layer on the first substrate, the first barrier insulating layer including a first contact hole, forming a pad part disposed on the first barrier insulating layer and inserted into the first contact hole, forming a second substrate on the pad part, the second substrate including a second contact hole, forming a first connection line disposed on the second substrate and inserted into the second contact hole to be connected to the pad part, forming an open part by etching a lower surface of the first substrate, the open part exposing the pad part and a lower surface of the first barrier insulating layer, disposing a lead electrode of a flexible film on the lower surface of the first barrier insulating layer so as to be spaced apart from the pad part in a plan view, and forming a contact part electrically connecting the pad part and the lead electrode to each other.

The forming of the contact part may comprise scanning coordinates of a center of the lead electrode protruding from the flexible film and coordinates of a center of the pad part exposed by the open part.

The forming of the contact part may further comprise printing and sintering metal paste between the center of the lead electrode and the center of the pad part.

The forming of the second substrate may comprise forming the second contact hole so as to be spaced apart from the first contact hole in the plan view.

The forming of the second substrate may comprise forming the second contact hole so as to overlap the first contact hole.

According to an embodiment, a method of manufacturing a display device comprises providing a first substrate, forming a first barrier insulating layer on the first substrate, the first barrier insulating layer including a plurality of first contact holes, forming a plurality of pad parts disposed on the first barrier insulating layer and inserted into the plurality of first contact holes, respectively, forming a second substrate on the plurality of pad parts, the second substrate including a plurality of second contact holes, forming a plurality of first connection lines disposed on the second substrate and inserted into the plurality of second contact holes, respectively, to be connected to the plurality of pad parts, respectively, forming an open part by etching a lower surface of the first substrate, the open part exposing the plurality of pad parts and a lower surface of the first barrier insulating layer, disposing lead electrodes of a flexible film on lower surfaces of the pad parts, forming a plurality of partition walls disposed between adjacent pad parts of the plurality of pad parts on the lower surface of the first barrier insulating layer, and forming contact parts connecting the pad parts and the lead electrodes to each other in a one-to-one manner.

The forming of the plurality of partition walls may comprise covering the pad parts and the lead electrodes with an organic material.

The forming of the plurality of partition walls may further comprise exposing the lead electrodes and the pad parts by etching portions of the organic material overlapping the lead electrodes.

The forming of the contact parts may comprise applying conductive ink between the partition walls and then sintering the conductive ink at a low temperature.

With a display device and a method of manufacturing the same according to embodiments, a contact part may be formed as a conductive line electrically connecting a lead electrode and a pad part spaced apart from each other to each other, and thus, may easily connect the lead electrode and the pad part to each other even when misalignment between the lead electrode and the pad part occurs. In addition, with the display device and the method of manufacturing the same, it is possible to reduce a manufacturing time and a manufacturing cost by minimizing an area of a non-display area and simplifying manufacturing processes.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view illustrating a display device according to an embodiment;

FIG. 2 is a cross-sectional view illustrating the display device according to an embodiment;

FIG. 3 is a cross-sectional view taken along line I-I′ of FIG. 1;

FIG. 4 is a bottom view illustrating the display device according to an embodiment;

FIG. 5 is a plan view illustrating a portion of a non-display area of the display device according to an embodiment;

FIG. 6 is a cross-sectional view illustrating a portion of the display device according to an embodiment;

FIG. 7 is a cross-sectional view illustrating a connection relationship between a pad part and a lead electrode in the display device according to an embodiment;

FIG. 8 is a bottom view illustrating the connection relationship between the pad part and the lead electrode in the display device according to an embodiment;

FIGS. 9, 10, to 11 are bottom views illustrating manufacturing processes of the display device according to an embodiment;

FIG. 12 is a cross-sectional view illustrating a portion of a display device according to another embodiment;

FIG. 13 is a cross-sectional view illustrating a connection relationship between a pad part and a lead electrode in the display device according to another embodiment;

FIG. 14 is a bottom view illustrating the connection relationship between the pad part and the lead electrode in the display device according to another embodiment;

FIGS. 15, 16, and 17 are cross-sectional views illustrating manufacturing processes of the display device according to another embodiment;

FIG. 18 is a cross-sectional view illustrating a portion of a display device according to another embodiment;

FIG. 19 is a cross-sectional view illustrating a connection relationship between a pad part and a lead electrode in the display device according to another embodiment;

FIG. 20 is a bottom view illustrating the connection relationship between the pad part and the lead electrode in the display device according to another embodiment;

FIG. 21 is a cross-sectional view illustrating partition walls in the display device according to another embodiment; and

FIGS. 22, 23, 24, and 25 are cross-sectional views illustrating manufacturing processes of the display device according to another embodiment.

### DETAILED DESCRIPTION OF THE EMBODIMENTS

In the following description, for the purposes of explanation, numerous specific details are set forth in order to provide a thorough understanding of various embodiments of the disclosure. As used herein “embodiments” are non-limiting examples of devices or methods employing one or more of the disclosure disclosed herein. It is apparent, however, that various embodiments may be practiced without these specific details or with one or more equivalent arrangements. In other instances, structures and devices are shown in block diagram form in order to avoid unnecessarily obscuring various embodiments. Further, various embodiments may be different, but do not have to be exclusive nor limit the disclosure. For example, specific shapes, configurations, and characteristics of an embodiment may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, or aspects, etc. (hereinafter individually or collectively referred to as “elements”), of the various embodiments may be otherwise combined, separated, interchanged, or rearranged without departing from the disclosure.

The use of cross-hatching or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, or any other characteristic, attribute, property, etc., of the elements, unless specified.

Further, in the accompanying drawings, the size and relative sizes of elements may be exaggerated for clarity or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of A, B, and C” and “at least one selected from the group consisting of A, B, and C” may be construed as A only, B only, C only, or any combination of two or more of A, B, and C, such as, for instance, ABC, ABB, BC, CC, or the like. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and “including,” when used in this specification, specify the presence of stated features, integers, steps, operations, elements, components, or groups thereof, but do not preclude the presence or addition of one or more other features, integers, steps, operations, elements, components, or groups thereof. It is also noted that, as used herein, the terms “substantially,” “about,” and other similar terms, are used as terms of approximation and not as terms of degree, and, as such, are utilized to account for inherent deviations in measured, calculated, or provided values that would be recognized by one of ordinary skill in the art.

Various embodiments are described herein with reference to sectional or exploded illustrations that are schematic illustrations of embodiments or intermediate structures. As such, variations from the shapes of the illustrations as a result, for example, of manufacturing techniques or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not necessarily intended to be limiting.

As customary in the field, some embodiments are described and illustrated in the accompanying drawings in terms of functional blocks, units, parts, or modules. Those skilled in the art will appreciate that these blocks, units, parts, or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, or modules being implemented by microprocessors or other similar hardware, they may be programmed and controlled using software (e.g., microcode) to perform various functions discussed herein and may optionally be driven by firmware or software. It is also contemplated that each block, unit, part, or module may be implemented by dedicated hardware, or as a combination of dedicated hardware to perform some functions and a processor (e.g., one or more programmed microprocessors and associated circuitry) to perform other functions. Also, each block, unit, part, or module of some embodiments may be physically separated into two or more interacting and discrete blocks, units, parts, or modules without departing from the scope of the disclosure. Further, the blocks, units, parts, or modules of some embodiments may be physically combined into more complex blocks, units, parts, or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, detailed embodiments of the disclosure is described with reference to the accompanying drawings.

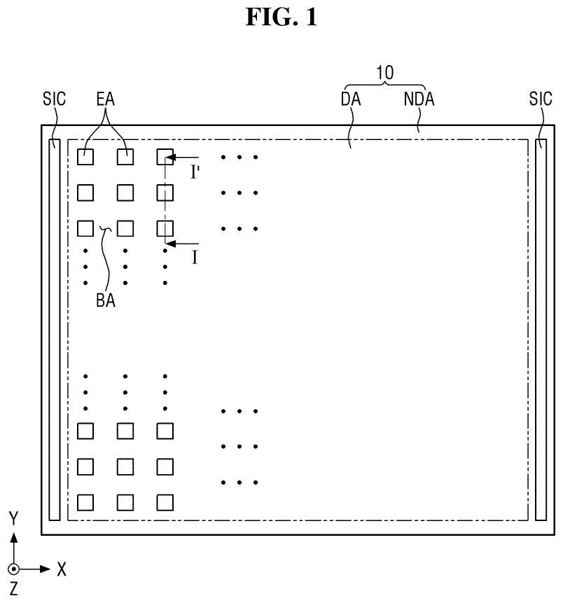

FIG. 1 is a plan view illustrating a display device according to an embodiment.

Referring to FIG. 1, a display device 10 may be applied to portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). As another example, the display device 10 may be applied as a display unit of televisions, laptop computers, monitors, billboards, or the Internet of Things (IOTs). As another example, the display device 10 may be applied to wearable devices such as smart watches, watch phones, glasses-type displays, and head mounted displays (HMDs).

The display device 10 may have a shape similar to a rectangular shape in plan view. For example, a corner of the display device 10 where a side in an X-axis direction and a side in a Y-axis direction meet may be rounded with a predetermined curvature or right-angled. The shape of the display device 10 in plan view is not limited to the rectangular shape, and may be a shape similar to other polygonal shapes, a circular shape, or an elliptical shape.

The display device 10 may include a display area DA and a non-display area NDA. The display area DA may include a plurality of pixels to display an image. Each of the plurality of pixels may include an organic light emitting diode (LED) including an organic light emitting layer, a quantum dot LED including a quantum dot light emitting layer, an inorganic LED including an inorganic semiconductor, or a micro LED. Hereinafter, it will be mainly described that each of the plurality of pixels includes an organic light emitting diode, but the present disclosure is not limited thereto.

The plurality of pixels may be arranged along a plurality of rows and columns in the display area DA. Each of the plurality of pixels may include an emission area EA defined by a pixel defining film or a bank, and may emit light having a predetermined peak wavelength through the emission area EA. The emission area EA may be an area in which light generated by a light emitting element of the display device 10 is emitted to the outside of the display device 10.

The display area DA of the display device 10 may include a light blocking area BA surrounding a plurality of emission areas EA. The light blocking area BA may prevent color mixing of light emitted from the emission areas EA.

The non-display area NDA may be disposed around the display area DA to surround the display area DA, and may not display an image. The non-display area NDA may include scan drivers SIC supplying scan signals to the display area DA. The scan drivers SIC may be disposed on the left side and the right side of the non-display area NDA. The scan drivers SIC may generate the scan signals based on a scan control signal. The scan control signal may include a start signal, a clock signal, and a source voltage, but is not limited thereto. The scan drivers SIC may supply the scan signals to scan lines of the display area DA according to a set order.

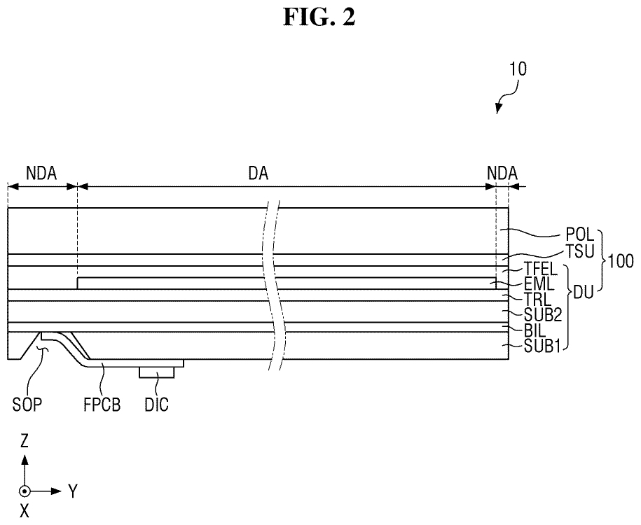

FIG. 2 is a cross-sectional view illustrating the display device according to an embodiment.

Referring to FIG. 2, a display panel 100 may include a display unit DU, a touch sensing unit TSU, and an optical member POL. The display unit DU may include a first substrate SUB1, a barrier insulating layer BIL, a second substrate SUB2, a transistor layer TRL, a light emitting element layer EML, and an encapsulation layer TFEL.

The first substrate SUB1 may support the display device 10. The first substrate SUB1 may be a base substrate or a base member. The first substrate SUB1 may be a flexible substrate that may be bent, folded, or rolled. As an example, the first substrate SUB1 may include an insulating material such as a polymer resin, for example, polyimide (PI), but is not limited thereto. As another example, the first substrate SUB1 may be a rigid substrate including a glass material.

The barrier insulating layer BIL may be disposed on the first substrate SUB1. The barrier insulating layer BIL may include an inorganic film capable of preventing permeation of air or moisture. For example, the barrier insulating layer BIL may include at least one of a silicon nitride layer, a silicon oxynitride layer, a silicon oxide layer, a titanium oxide layer, an aluminum oxide layer, and an amorphous silicon layer, but is not limited thereto.

The second substrate SUB2 may be disposed on the barrier insulating layer BIL. The second substrate SUB2 may be a base substrate or a base member. The second substrate SUB2 may be a flexible substrate that may be bent, folded, or rolled. For example, the second substrate SUB2 may include an insulating material such as a polymer resin, for example, polyimide (PI), but is not limited thereto.

The transistor layer TRL may be disposed on the second substrate SUB2. The transistor layer TRL may include a plurality of transistors constituting pixel circuits of pixels. The transistor layer TRL may include scan lines, data lines, and power lines connected to the pixels. Each of the transistors may include a semiconductor region, a source electrode, a drain electrode, and a gate electrode. For example, when the scan driver is formed on one side of the non-display area NDA of the display panel 100, the scan driver may include transistors.

The transistor layer TRL may be disposed in the display area DA and the non-display area NDA. The transistors of each of the pixels, the scan lines, the data lines, and the power lines of the transistor layer TRL may be disposed in the display area DA. The transistors of the scan driver SIC may be disposed in the non-display area NDA.

The light emitting element layer EML may be disposed on the transistor layer TRL. The light emitting element layer EML may include a plurality of light emitting elements in which a pixel electrode, a light emitting layer, and a common electrode are sequentially stacked to emit light and a pixel defining film defining pixels. The plurality of light emitting elements of the light emitting element layer EML may be disposed in the display area DA.

For example, the light emitting layer may be an organic light emitting layer including an organic material. The light emitting layer may include a hole transporting layer, an organic light emitting layer, and an electron transporting layer. When the pixel electrode receives a predetermined voltage through the transistor of the transistor layer TRL and the common electrode receives a cathode voltage, holes and electrons may move to the organic light emitting layer through the hole transporting layer and the electrode transporting layer, respectively, and may combine with each other in the organic light emitting layer to emit the light. For example, the pixel electrode may be an anode electrode and the common electrode may be a cathode electrode, but the present disclosure is not limited thereto.

As another example, the plurality of light emitting elements may include quantum dot light emitting diodes including a quantum dot light emitting layer, inorganic light emitting diodes including an inorganic semiconductor, or micro light emitting diodes.

The encapsulation layer TFEL may cover an upper surface and side surfaces of the light emitting element layer EML, and may protect the light emitting element layer EML. The encapsulation layer TFEL may include at least one inorganic film and at least one organic film for encapsulating the light emitting element layer EML.

The touch sensing unit TSU may be disposed on the encapsulation layer TFEL. The touch sensing unit TSU may include a plurality of touch electrodes for sensing a user's touch in a capacitance manner and touch lines for supplying touch driving signals to the plurality of touch electrodes. For example, the touch sensing unit TSU may sense the user's touch in a mutual capacitance manner or a self-capacitance manner.

The plurality of touch electrodes of the touch sensing unit TSU may be disposed in a touch sensor area overlapping the display area DA. The touch lines of the touch sensing unit TSU may be disposed in a touch peripheral area overlapping the non-display area NDA.

The optical member POL may be disposed on the touch sensing unit TSU. The optical member POL may be attached onto the touch sensing unit TSU by an optically clear adhesive (OCA) film or an optically clear resin (OCR). For example, the optical member POL may include a linear polarizer and a phase retardation film, and the phase retardation film may be a λ/4 plate (quarter-wave plate). The phase retardation film and the linear polarizer may be sequentially stacked on the touch sensing unit TSU. The optical member POL may prevent distortion of colors due to external light reflection by reducing reflected light by external light.

The first substrate SUB1 may include an open part SOP. The open part SOP of the first substrate SUB1 may be etched from a lower surface of the first substrate SUB1 to extend through the first substrate SUB1. For example, a width of a lower portion of the open part SOP may be greater than a width of an upper portion of the open part SOP. In manufacturing processes of the display device 10, a pad part provided on the barrier insulating layer BIL may be exposed by the open part SOP of the first substrate SUB1. The pad part may be electrically connected to a display driver DIC through a flexible film FPCB inserted into the open part SOP.

The flexible film FPCB may be disposed below the first substrate SUB1. A portion of the flexible film FPCB may be inserted into the open part SOP of the first substrate SUB1 to be electrically connected to the pad part. The flexible film FPCB may support the display driver DIC. The flexible film FPCB may transmit a signal and a voltage of the display driver DIC to the transistor layer TRL. The flexible film FPCB may supply a scan control signal to the scan driver SIC.

The display driver DIC may be mounted on the flexible film FPCB. The display driver DIC may be an integrated circuit (IC). The display driver DIC may convert digital video data into an analog data voltage based on a data control signal received from a timing controller (not illustrated), and may supply the analog data voltage to the data line of the display area DA through the flexible film FPCB. The display driver DIC may supply a source voltage received from a power supply unit (not illustrated) to the power line of the display area DA through the flexible film FPCB. The display device 10 includes the flexible film FPCB electrically connected to the pad part at the open part SOP of the first substrate SUB1, and thus, an area of the non-display area NDA may be minimized.

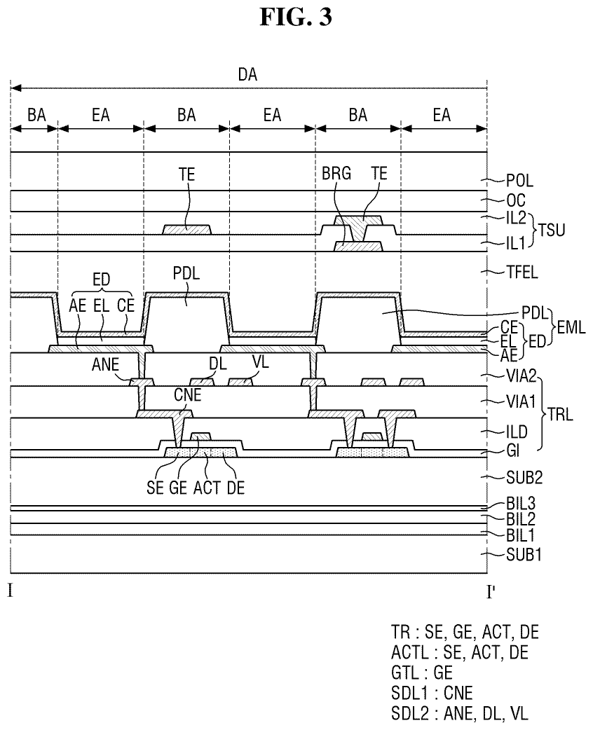

FIG. 3 is a cross-sectional view taken along line I-I′ of FIG. 1.

Referring to FIG. 3, the display area DA of the display device 10 may include a plurality of emission areas EA. Each of the emission areas EA may be an area in which light generated by a light emitting element ED is emitted to the outside of the display device 10.

The display panel 100 may include a first substrate SUB1, a first barrier insulating layer BIL1, a second barrier insulating layer BIL2, a third barrier insulating layer BIL3, a second substrate SUB2, a transistor layer TRL, a light emitting element layer EML, an encapsulation layer TFEL, a touch sensing unit TSU, a planarization layer OC, and an optical member POL.

The first substrate SUB1 may support the display panel 100. The first substrate SUB1 may be a base substrate or a base member. The first substrate SUB1 may be a flexible substrate that may be bent, folded, or rolled. As an example, the first substrate SUB1 may include an insulating material such as a polymer resin, for example, polyimide (PI), but is not limited thereto. As another example, the first substrate SUB1 may be a rigid substrate including a glass material.

The first barrier insulating layer BIL1 may be disposed on the first substrate SUB1. The first barrier insulating layer BIL1 may include an inorganic film capable of preventing permeation of air or moisture. For example, the first barrier insulating layer BIL1 may include at least one of a silicon nitride layer, a silicon oxynitride layer, a silicon oxide layer, a titanium oxide layer, an aluminum oxide layer, and an amorphous silicon layer, but is not limited thereto.

The second barrier insulating layer BIL2 may be disposed on the first barrier insulating layer BIL1. The second barrier insulating layer BIL2 may include an inorganic film capable of preventing permeation of air or moisture. For example, the second barrier insulating layer BIL2 may include at least one of a silicon nitride layer, a silicon oxynitride layer, and a silicon oxide layer, but is not limited thereto.

The third barrier insulating layer BIL3 may be disposed on the second barrier insulating layer BIL2. The third barrier insulating layer BIL3 may include an inorganic film capable of preventing permeation of air or moisture. The third barrier insulating layer BIL3 may improve a peeling defect by increasing adhesive strength between upper and lower layers. For example, the third barrier insulating layer BIL3 may include amorphous silicon (a-Si), but is not limited thereto.

The second substrate SUB2 may be disposed on the third barrier insulating layer BIL3. The second substrate SUB2 may be a base substrate or a base member. The second substrate SUB2 may be a flexible substrate that may be bent, folded, or rolled. For example, the second substrate SUB2 may include an insulating material such as a polymer resin, for example, polyimide (PI), but is not limited thereto.

The transistor layer TRL may be disposed on the second substrate SUB2. The transistor layer TRL may include an active layer ACTL, a gate insulating layer GI, a gate layer GTL, an interlayer insulating layer ILD, a first source metal layer SDL1, a first via layer VIA1, a second source metal layer SDL2, and a second via layer VIA2.

The active layer ACTL may be disposed on the second substrate SUB2. The active layer ACTL may include a semiconductor region ACT, a drain electrode DE, and a source electrode SE of a transistor TR. The semiconductor region ACT may overlap a gate electrode GE, and may be insulated from the gate electrode GE by the gate insulating layer GI. The drain electrode DE and the source electrode SE may be provided by making a material of the semiconductor region ACT conductors. The transistor TR may constitute the pixel circuit of each of the plurality of pixels.

The gate insulating layer GI may be disposed on the active layer ACTL. The gate insulating layer GI may insulate the semiconductor region ACT and the gate electrode GE of the transistor TR from each other. The gate insulating layer GI may include a contact hole through which a connection electrode CNE penetrates.

The gate layer GTL may be disposed on the gate insulating layer GI. The gate layer GTL may include the gate electrode GE of the transistor TR. The gate electrode GE may overlap the semiconductor region ACT with the gate insulating layer GI interposed therebetween. The gate electrode GE may receive a scan signal from a scan line. For example, the gate layer GTL may be formed as a single layer or multiple layers including at least one of molybdenum (Mo), aluminum (Al), chromium (Cr), gold (Au), silver (Ag), titanium (Ti), nickel (Ni), palladium (Pd), indium (In), neodymium (Nd), and copper (Cu).

The interlayer insulating layer ILD may be disposed on the gate layer GTL. The interlayer insulating layer ILD may insulate the gate layer GTL and the first source metal layer SDL1 from each other. The interlayer insulating layer ILD may include a contact hole through which the connection electrode CNE penetrates.

The first source metal layer SDL1 may be disposed on the interlayer insulating layer ILD. The first source metal layer SDL1 may include the connection electrode CNE. The connection electrode CNE may be inserted into the contact hole penetrating through the interlayer insulating layer ILD and the gate insulating layer GI to be connected to the source electrode SE of the transistor TR. The connection electrode CNE may electrically connect the transistor TR and an anode connection electrode ANE to each other. The connection electrode CNE may supply a driving current received from the pixel circuit to the light emitting element ED through the anode connection electrode ANE. For example, the first source metal layer SDL1 may be formed as a single layer or multiple layers including at least one of molybdenum (Mo), aluminum (Al), chromium (Cr), gold (Au), silver (Ag), titanium (Ti), nickel (Ni), palladium (Pd), indium (In), neodymium (Nd), and copper (Cu).

The first via layer VIA1 may be disposed on the first source metal layer SDL1. The first via layer VIA1 may planarize an upper end of the pixel circuit and protect the pixel circuit. The first via layer VIA1 may include an organic insulating material such as polyimide (PI). The first via layer VIA1 may include a contact hole through which the anode connection electrode ANE penetrates.

The second source metal layer SDL2 may be disposed on the first source metal layer SDL1. The second source metal layer SDL2 may include the anode connection electrode ANE, a data line DL, and a power line VL. The second source metal layer SDL2 may include the material exemplified in the first source metal layer SDL1.

The anode connection electrode ANE may be inserted into the contact hole penetrating through the first via layer VIA1 to be connected to the connection electrode CNE. The anode connection electrode ANE may electrically connect the connection electrode CNE and a pixel electrode AE of the light emitting element ED to each other. The anode connection electrode ANE may supply the driving current received from the connection electrode CNE to the light emitting element ED.

The data line DL may extend in the Y-axis direction in the display area DA. The data line DL may be electrically connected to the transistor TR. The data line DL may supply a data voltage to the pixel circuit.

The power line VL may extend in the Y-axis direction in the display area DA. The power line VL may be electrically connected to the transistor TR or the light emitting element ED. For example, the power line VL may be a high potential line, a low potential line, an initialization voltage line, a reference voltage line, or a bias voltage line, but is not limited thereto.

The second via layer VIA2 may be disposed on the second source metal layer SDL2. The second via layer VIA2 may planarize an upper end of the transistor layer TRL. The second via layer VIA2 may include an organic insulating material such as polyimide (PI). The second via layer VIA2 may include a contact hole through which the pixel electrode AE penetrates.

The light emitting element layer EML may be disposed on the transistor layer TRL. The light emitting element layer EML may include the light emitting element ED and a pixel defining film PDL.

The light emitting element ED may be disposed in the emission area EA on the second via layer VIA2. The light emitting element ED of each of the plurality of pixels may include the pixel electrode AE, a light emitting layer EL, and a common electrode CE. The pixel electrode AE may be disposed on the second via layer VIA2. The pixel electrode AE may overlap one of the plurality of emission areas EA defined by the pixel defining film PDL. For example, the pixel electrode AE may receive the driving current from the pixel circuit through the anode connection electrode ANE and the connection electrode CNE.

The light emitting layer EL may be disposed on the pixel electrode AE. For example, the light emitting layer EL may be an organic light emitting layer made of an organic material, but is not limited thereto. In a case where the light emitting layer EL is the organic light emitting layer, when the pixel circuit of the pixel applies a predetermined voltage to the pixel electrode AE and the common electrode CE receives a common voltage or a cathode voltage, holes and electrons may move to the light emitting layer EL through a hole transporting layer and an electron transporting layer, respectively, and may be combined with each other in the light emitting layer EL to emit light.

The common electrode CE may be disposed on the light emitting layer EL. For example, the common electrode CE is not divided for each of the plurality of pixels, and may be implemented in the form of an electrode common to all the pixels. The common electrode CE may be disposed on the light emitting layers EL in the plurality of emission areas, and may be disposed on the pixel defining film PDL in areas other than the plurality of emission areas.

The pixel defining film PDL may be disposed in the light blocking area BA on the second via layer VIA2. The pixel defining film PDL may define the plurality of emission areas EA or a plurality of opening areas. The pixel defining film PDL may allow the pixel electrodes AE of the plurality of pixels to be spaced apart and insulated from each other.

The encapsulation layer TFEL may be disposed on the common electrode CE to cover the plurality of light emitting elements ED. The encapsulation layer TFEL may include at least one inorganic film to prevent oxygen or moisture from permeating into the plurality of light emitting elements ED. The encapsulation layer TFEL may include at least one organic film to protect the plurality of light emitting elements ED from foreign substances such as dust.

The touch sensing unit TSU may be disposed on the encapsulation layer TFEL. The touch sensing unit TSU may include a bridge electrode BRG, a first insulating layer IL1, touch electrodes TE, and a second insulating layer IL2.

The bridge electrode BRG may be disposed on the encapsulation layer TFEL. The bridge electrode BRG may be disposed at a different layer from the touch electrodes TE and may electrically connect adjacent touch electrodes TE to each other.

The first insulating layer IL1 may be disposed on the bridge electrode BRG. The first insulating layer IL1 may have insulating and optical functions. As an example, the first insulating layer IL1 may be an inorganic film including at least one of a silicon nitride layer, a silicon oxynitride layer, a silicon oxide layer, a titanium oxide layer, and an aluminum oxide layer. As another example, the first insulating layer IL1 may include an organic film.

The touch electrodes TE may be disposed in the light blocking area BA on the first insulating layer IL1. The touch electrodes TE may sense a user's touch in a capacitance manner. For example, the touch sensing unit TSU may sense the user's touch in a mutual capacitance manner in which capacitance is formed between a plurality of touch electrodes TE or a self-capacitance manner in which capacitance is formed in each of the plurality of touch electrodes TE. The touch electrode TE may be formed as a single layer made of molybdenum (Mo), titanium (Ti), copper (Cu), aluminum (Al), or indium tin oxide (ITO) or be formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

The second insulating layer IL2 may be disposed on the touch electrodes TE. The second insulating layer IL2 may have insulating and optical functions. The second insulating layer IL2 may be made of the material exemplified in the first insulating layer IL1.

The planarization layer OC may be disposed on the touch sensing unit TSU to planarize an upper end of the touch sensing unit TSU. For example, the planarization layer OC may include an organic insulating material.

The optical member POL may be disposed on the planarization layer OC. The optical member POL may be attached onto the touch sensing unit TSU by an optically clear adhesive (OCA) film or an optically clear resin (OCR). For example, the optical member POL may include a linear polarizer and a phase retardation film, and the phase retardation film may be a λ/4 plate (quarter-wave plate). The phase retardation film and the linear polarizer may be sequentially stacked on the touch sensing unit TSU. The optical member POL may prevent distortion of colors due to external light reflection by reducing reflected light by external light.

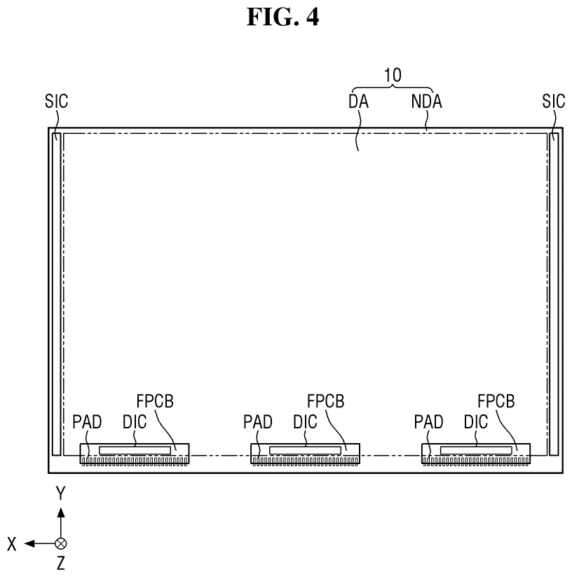

FIG. 4 is a bottom view illustrating the display device according to an embodiment.

Referring to FIG. 4, the flexible films FPCB may be disposed below the first substrate SUB1. The flexible films FPCB may be disposed at an edge of a lower surface of the display panel 100. The flexible films FPCB may be attached to lower surfaces of pad parts PAD through adhesive members. Lead electrodes of the flexible films FPCB may be electrically connected to the pad parts PAD through contact parts. The pad parts PAD may be disposed in the non-display area NDA, but are not limited thereto.

The display drivers DIC may be mounted on the flexible films FPCB. The display driver DIC may be an integrated circuit (IC). The display driver DIC may convert digital video data into an analog data voltage based on a data control signal received from a timing controller (not illustrated), and may supply the analog data voltage to the data line DL of the display area DA through the flexible film FPCB. The display driver DIC may supply a source voltage received from a power supply unit (not illustrated) to the power line VL of the display area DA through the flexible film FPCB. The display driver DIC may supply a scan control signal to the scan driver SIC through the flexible film PFCB. The display device 10 includes the pad part PAD disposed on the first substrate SUB1 and the flexible film FPCB and the display driver DIC disposed below the first substrate SUB1, such that an area of the non-display area NDA may be minimized.

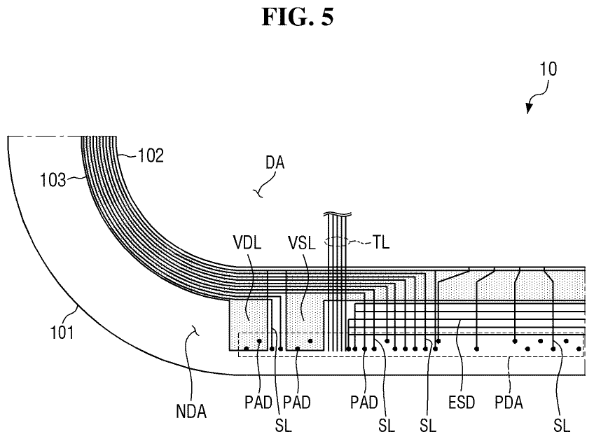

FIG. 5 is a plan view illustrating a portion of a non-display area of the display device according to an embodiment.

Referring to FIG. 5, the non-display area NDA may include signal lines SL, a high potential line VDL, a low potential line VSL, and touch lines TL. The signal lines SL, the high potential line VDL, the low potential line VSL, and the touch lines TL may extend from a pad area PDA to the display area DA. The signal line SL may be electrically connected to the data line DL to supply the data voltage, and may be electrically connected to the scan driver SIC to supply the scan control signal. The high potential line VDL may be electrically connected to the power line VL of the display area DA to supply a high potential voltage to the pixel circuit. The low potential line VSL may be electrically connected to the common electrode CE of the light emitting element ED to supply a low potential voltage. The touch lines TL may be electrically connected to the touch electrodes TE of the touch sensing unit TSU to supply touch driving signals. The signal lines SL, the high potential line VDL, the low potential line VSL, and the touch lines TL may receive signals or voltages from the flexible films FPCB disposed below the display panel 100 through the pad parts PAD.

The non-display area NDA may further include an anti-static circuit ESD. The anti-static circuit ESD may overlap the signal line SL, and may be electrically connected to the signal line SL. Accordingly, the anti-static circuit ESD may prevent static electricity introduced from the outside from being introduced into the display area DA through the signal line SL.

A solid line 101 in FIG. 5 indicates a boundary of the display panel 100 corresponding to any one corner of the display panel 100. A solid line 102 in FIG. 5 is a virtual line indicating a boundary between the non-display area NDA and the display area DA of the display panel 100. A solid line 103 in FIG. 5 is a line indicating a boundary to which the encapsulation layer TFEL of the display panel 100 is disposed in any one corner of the display panel 100. The signal line SL, the high potential line VDL, and the low potential line VSL may extend to the pad parts PAD along the non-display area NDA inside the boundary to which the encapsulation layer TFEL is disposed. The signal line SL, the high potential line VDL, and the low potential line VSL may not be disposed outside the boundary to which the encapsulation layer TFEL.

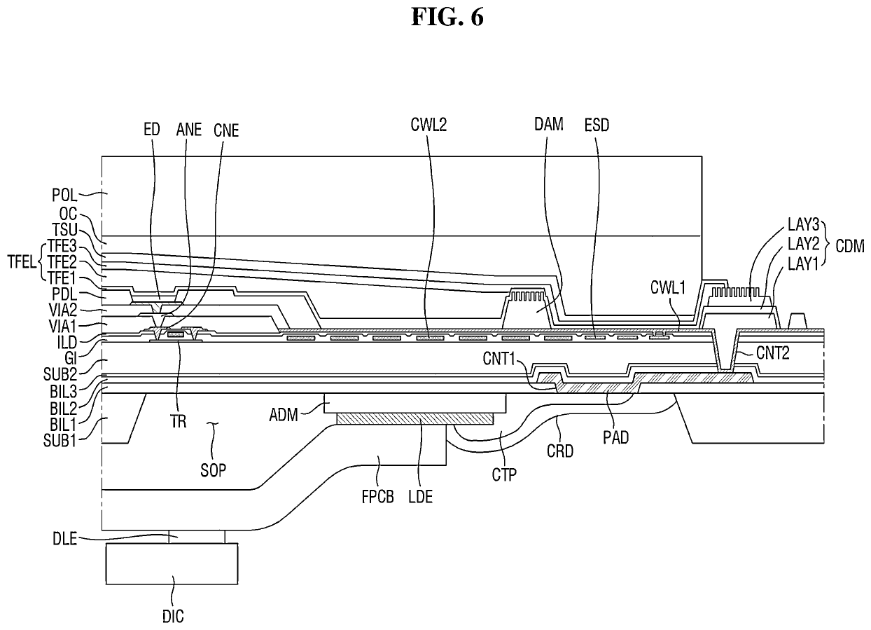

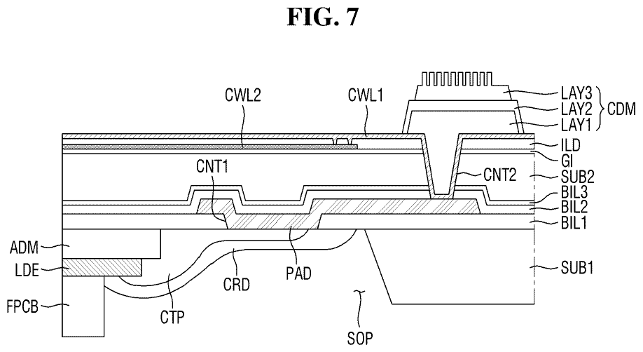

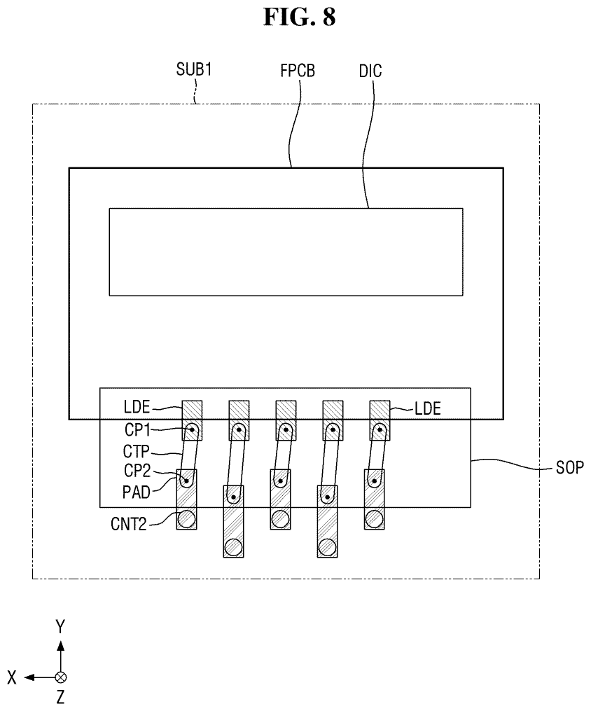

FIG. 6 is a cross-sectional view illustrating a portion of the display device according to an embodiment, FIG. 7 is a cross-sectional view illustrating a connection relationship between a pad part and a lead electrode in the display device according to an embodiment, and FIG. 8 is a bottom view illustrating the connection relationship between the pad part and the lead electrode in the display device according to an embodiment. Hereinafter, the same configurations as the configurations described above will be briefly described or a description thereof will be omitted.

Referring to FIGS. 6 to 8, the display device 10 may include a first substrate SUB1, a first barrier insulating layer BIL1, a pad part PAD, a second barrier insulating layer BIL2, a third barrier insulating layer BIL3, a second substrate SUB2, a transistor layer TRL (FIG. 3), a light emitting element layer EML (FIG. 3), an encapsulation layer TFEL, a dam DAM, an anti-static circuit ESD, a crack prevention part CDM, a touch sensing unit TSU, a planarization layer OC, an optical member POL, a flexible film FPCB, and a display driver DIC.

The pad part PAD may be disposed on the first barrier insulating layer BIL1 and inserted into a first contact hole CNT1 provided in the first barrier insulating layer BIL1. In manufacturing processes of the display device 10, a lower surface of the pad part PAD may be exposed through an open part SOP of the first substrate SUB1. The pad part PAD may electrically connect the flexible film FPCB and a first connection line CWL1 to each other. The pad part PAD may be spaced apart from a lead electrode LDE of the flexible film FPCB in plan view. The pad part PAD may be electrically connected to the lead electrode LDE of the flexible film FPCB through a contact part CTP. The pad part PAD may be formed as a single layer or multiple layers including at least one of molybdenum (Mo), aluminum (Al), chromium (Cr), gold (Au), silver (Ag), titanium (Ti), nickel (Ni), palladium (Pd), indium (In), neodymium (Nd), and copper (Cu).

The second barrier insulating layer BIL2 may be disposed on the pad part PAD. The second barrier insulating layer BIL2 may include a second contact hole CNT2 into which the first connection line CWL1 is inserted. In the manufacturing processes of the display device 10, an upper surface of the pad part PAD may be exposed through the second contact hole CNT2.

The third barrier insulating layer BIL3 may be disposed on the second barrier insulating layer BIL2. The third barrier insulating layer BIL3 may improve a peeling defect by increasing adhesive strength between upper and lower layers. For example, the third barrier insulating layer BIL3 may include amorphous silicon (a-Si), but is not limited thereto.

The second substrate SUB2 may be disposed on the third barrier insulating layer BIL3. The second substrate SUB2 may be a base substrate or a base member. The second substrate SUB2 may be a flexible substrate that may be bent, folded, or rolled. For example, the second substrate SUB2 may include an insulating material such as a polymer resin, for example, polyimide (PI), but is not limited thereto.

The gate insulating layer GI may be disposed on the second substrate SUB2, and the interlayer insulating layer ILD may be disposed on the gate insulating layer GI. The interlayer insulating layer ILD, the gate insulating layer GI, the second substrate SUB2, the third barrier insulating layer BIL3, and the second barrier insulating layer BIL2 may include a second contact hole CNT2. The second contact hole CNT2 may be etched from an upper surface of the interlayer insulating layer ILD to extend through the second barrier insulating layer BIL2. In a process of forming the second contact hole CNT2, an upper surface of the pad part PAD may be exposed. The first and second contact holes CNT1 and CNT2 may be spaced apart from each other in plan view.

The first connection line CWL1 may be disposed on the interlayer insulating layer ILD. The first connection line CWL1 may include the same material as the first source metal layer SDL1 of the display area DA and may be formed in the same process as the first source metal layer SDL1. A portion of the first connection line CWL1 may be inserted into the second contact hole CNT2 to be in contact with the upper surface of the pad part PAD. The other portion of the first connection line CWL1 may penetrate through the interlayer insulating layer ILD to be in contact with a second connection line CWL2. The first connection line CWL1 may electrically connect the pad part PAD and the second connection line CWL2 to each other. The first connection line CWL1 may supply a data voltage or a source voltage received from the pad part PAD to the second connection line CWL2.

The second connection line CWL2 may be disposed on the gate insulating layer GI. The second connection line CWL2 may include the same material as the gate layer GTL of the display area DA and may be formed in the same process as the gate layer GTL. The second connection line CWL2 may supply the data voltage received from the first connection line CWL1 to the data line DL The second connection line CWL2 and may supply the source voltage received from the first connection line CWL1 to the power line VL. For example, the second connection line CWL2 may correspond to the signal line SL in FIG. 5 or may be electrically connected to the signal line SL.

The encapsulation layer TFEL may include first to third encapsulation layers TFE1, TFE2, and TFE3.

The first encapsulation layer TFE1 may be disposed on the light emitting element layer EML. The first encapsulation layer TFE1 may include an inorganic material to prevent oxygen or moisture from permeating into the light emitting element layer EML. The first encapsulation layer TFE1 may extend to the crack prevention part CDM beyond the display area DA and the dam DAM. The first encapsulation layer TFE1 may include at least one of a silicon nitride layer, a silicon oxynitride layer, a silicon oxide layer, a titanium oxide layer, an aluminum oxide layer, and an amorphous silicon layer, but is not limited thereto.

The second encapsulation layer TFE2 may be disposed on the first encapsulation layer TFE1. The second encapsulation layer TFE2 may include an organic material to protect the light emitting element layer EML from foreign substances such as dust. The second encapsulation layer TFE2 may extend to the dam DAM beyond the display area DA. The second encapsulation layer TFE2 may be filled and formed within an area surrounded by the dam DAM. The second encapsulation layer TFE2 may include an organic film made of an acrylic resin, an epoxy resin, a phenolic resin, a polyamide resin, a polyimide resin, or the like. The second encapsulation layer TFE2 may be formed by curing a monomer or applying a polymer.

The third encapsulation layer TFE3 may be disposed on the second encapsulation layer TFE2. The third encapsulation layer TFE3 may include an inorganic material to prevent oxygen or moisture from permeating into the light emitting element layer EML. The third encapsulation layer TFE3 may extend to the crack prevention part CDM beyond the display area DA and the dam DAM. The third encapsulation layer TFE3 may be disposed on the second encapsulation layer TFE2 inside the dam DAM, and may be disposed on the first encapsulation layer TFE1 from the dam DAM to the crack prevention part CDM. The third encapsulation layer TFE3 may be made of the same material as the first encapsulation layer TFE1.

The dam DAM may surround the display area DA. The dam DAM may include the same material as the pixel defining film PDL and may be formed in the same process as the pixel defining film PDL. The dam DAM may have a predetermined height so that the second encapsulation layer TFE2 including the organic material does not go beyond the dam DAM.

The anti-static circuit ESD may be disposed between the display area DA and the crack prevention part CDM. The anti-static circuit ESD may include at least one transistor. The anti-static circuit ESD may be electrically connected to the second connection line CWL2. The anti-static circuit ESD may prevent static electricity introduced from the outside from being introduced into the display area DA through the second connection line CWL2.

The crack prevention part CDM may surround the dam DAM. The crack prevention part CDM may be disposed at the outermost portion of the display panel 100 and prevent a crack of the display panel 100. The first and third encapsulation layers TFE1 and TFE3 and the planarization layer OC may be formed within an area surrounded by the crack prevention part CDM.

The crack prevention part CDM may include first to third layers LAY1, LAY2, and LAY3. The first layer LAY1 of the crack prevention part CDM may cover an upper surface of the first connection line CWL1 inserted into the second contact hole CNT2. The first layer LAY1 may fill a hole formed by the first contact line CW1 in the second contact hole CNT2. The first layer LAY1 may include the same material as the first via layer VIA1 and may be formed in the same process as the first via layer VIA1.

The second layer LAY2 of the crack prevention part CDM may be disposed on the first layer LAY1. The second layer LAY2 may include the same material as the second via layer VIA2 and may be formed in the same process as the second via layer VIA2.

The third layer LAY3 of the crack prevention part CDM may be disposed on the second layer LAY2. The third layer LAY3 may include the same material as the pixel defining film PDL and may be formed in the same process as the pixel defining film PDL.

The first substrate SUB1 may include the open part SOP. The open part SOP of the first substrate SUB1 may be etched from a lower surface of the first substrate SUB1 to extend through the first substrate SUB1. For example, a width of a lower portion of the open part SOP may be greater than a width of an upper portion of the open part SOP. In the manufacturing processes of the display device 10, a lower surface of the first barrier insulating layer BIL1 and the lower surface of the pad part PAD may be exposed through the open part SOP.

The flexible film FPCB may be disposed below the first substrate SUB1. A portion of the flexible film FPCB may be inserted into the open part SOP of the first substrate SUB1 to be electrically connected to the pad part PAD. The flexible film FPCB may include the lead electrode LDE disposed on an upper surface of one side thereof and inserted into the open part SOP. The lead electrode LDE may protrude from one side of the flexible film FPCB, and a protruding portion of the lead electrode LDE may not overlap the flexible film FPCB. The lead electrode LDE may be attached to the lower surface of the first barrier insulating layer BIL1 through an adhesive member ADM. The lead electrode LDE may be spaced apart from the pad part PAD in a plan view. The lead electrode LDE may be electrically connected to the pad part PAD through the contact part CTP.

The flexible film FPCB may support the display driver DIC disposed on a lower surface of the flexible film FPCB. The lead electrode LDE may be electrically connected to the display driver DIC through a lead line (not illustrated) provided on the flexible film FPCB. The other side of the flexible film FPCB may be connected to a source circuit board (not illustrated) below the first substrate SUB1. The flexible film FPCB may transmit a signal and a voltage of the display driver DIC to the display device 10. The flexible film FPCB may supply a scan control signal to the scan driver SIC.

The display driver DIC may be mounted on the flexible film FPCB. The display driver DIC may be an integrated circuit (IC). The display driver DIC may convert digital video data into an analog data voltage based on a data control signal received from a timing controller (not illustrated), and may supply the analog data voltage to the data line DL of the display area DA through the flexible film FPCB. The display driver DIC may supply a source voltage received from a power supply unit (not illustrated) to the power line VL of the display area DA through the flexible film FPCB. The display device 10 includes the pad part PAD disposed on the first substrate SUB1, and the flexible film FPCB and the display driver DIC disposed below the first substrate SUB1 such that an area of the non-display area NDA may be minimized.

In FIG. 8, the contact part CTP may electrically connect the lead electrode LDE and the pad part PAD to each other. The contact part CTP may correspond to a conductive line disposed between the lead electrode LDE and the pad part PAD spaced apart from each other. The contact part CTP may partially cover a lower surface of the lead electrode LDE protruding from the flexible film FPCB and the lower surface of the pad part PAD exposed through the open part SOP. The contact part CTP may partially cover the lower surface of the first barrier insulating layer BIL1 disposed between the lead electrode LDE and the pad part PAD. The contact part CTP may be a conductive line connecting the center CP1 of the lead electrode LDE protruding from the flexible film FPCB and the center CP2 of the pad part PAD inserted into the first contact hole CNT1 to each other. The contact part CTP may overlap the first contact hole CNT1 and may not overlap the second contact hole CNT2. Each of a plurality of contact parts CTP may connect one of a plurality of lead electrodes LDE and a pad part PAD corresponding to the one lead electrode LDE to each other in a one-to-one manner. The contact part CTP may easily connect the lead electrode LED and the pad part PAD to each other by connecting the lead electrode LDE and the pad part PAD to each other in a one-to-one manner even when misalignment occurs in a process of aligning the lead electrode LDE and the pad part PAD with each other. The plurality of contact parts CTP are individually formed without a separate laser patterning process, and thus, it is possible to prevent damage to the display panel 100, a short-circuit defect, and an over-sintering risk of the contact parts CTP due to laser patterning.

As an example, the contact part CTP may be formed by low temperature sintering of conductive ink including nanoparticles and a polymer. The nanoparticles may include nanoscale metal particles such as silver (Ag), copper (Cu), aluminum (Al), or chromium (Cr), and the polymer may include an acrylic resin or an epoxy resin, but the present disclosure is not limited thereto. The conductive ink may include the polymer as a binder binding the metal particles to each other, and the nanoparticles may be in close contact with each other and agglomerate through a sintering process. The contact part CTP may have conductivity by including the sintered nanoparticles.

As another example, the contact part CTP may be formed by low temperature sintering of metal organic decomposition ink (MOD ink). The metal organic decomposition ink may include liquid-phase metal organic decomposition materials smaller than the nanoparticles, and the liquid-phase metal organic decomposition materials may be changed into metal materials through a sintering process. Accordingly, the contact part CTP may have conductivity.

The contact part CTP may be formed by printing conductive ink or metal paste on the open part SOP of the first substrate SUB1 using a silicon pad and then sintering the conductive ink or the metal paste using intense pulsed light (IPL) or a laser. The metal particles are in close contact with each other and agglomerate due to heat generated by the IPL or the laser in the sintering process, such that specific resistance of the contact part CTP may be reduced.

The display device 10 may reduce a manufacturing time and a manufacturing cost by electrically connecting the lead electrode LDE and the pad part PAD to each other through the contact part CTP using the conductive ink or the metal paste to simplify manufacturing processes without using ultrasonic bonding or thermocompression bonding.

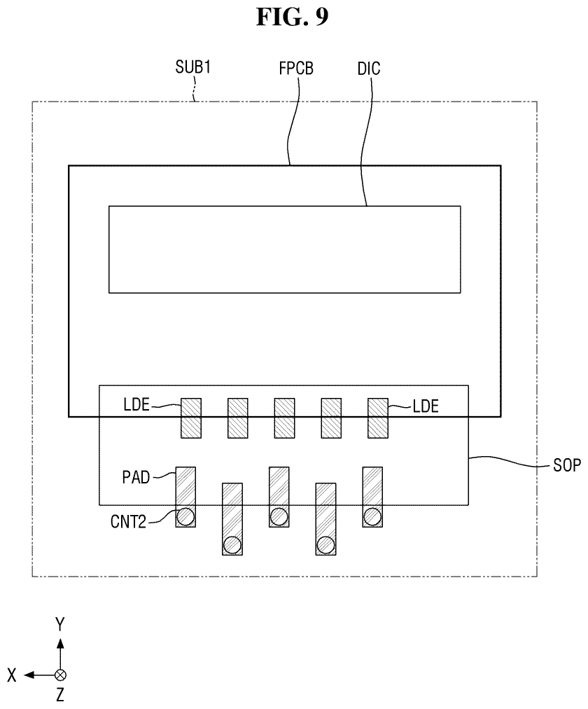

FIGS. 9 to 11 are bottom views illustrating manufacturing processes of the display device according to an embodiment.

In FIG. 9, the flexible films FPCB may be disposed below the first substrate SUB1. One side of the flexible film FPCB may be inserted into the open part SOP of the first substrate SUB1. The lead electrode LDE of the flexible film FPCB may be disposed to be spaced apart from the pad part PAD in the Y-axis direction. The lead electrode LDE may protrude from one side of the flexible film FPCB, and a protruding portion of the lead electrode LDE may not overlap the flexible film FPCB. The lead electrode LDE may be attached to the lower surface of the first barrier insulating layer BIL1 through the adhesive member ADM. For example, the lead electrode LDE and the pad part PAD may be disposed on a virtual line extending in the Y-axis direction, but are not limited thereto.

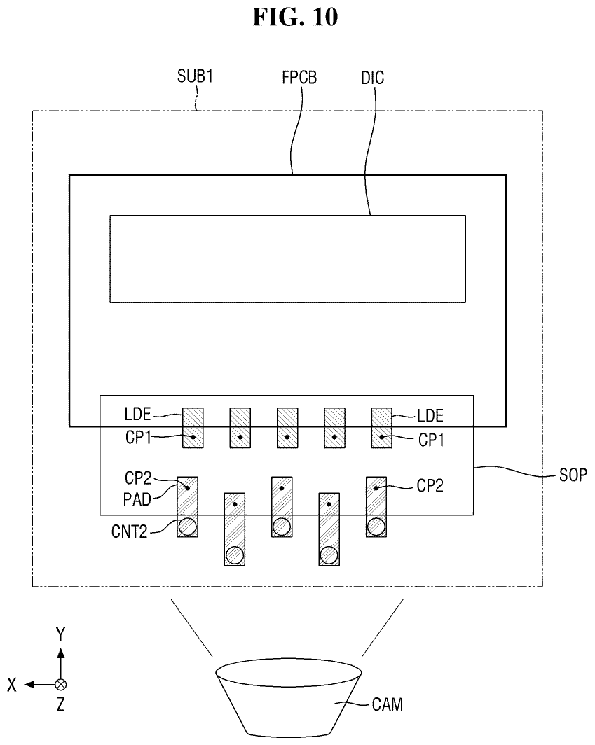

In FIG. 10, a camera CAM may scan coordinates of the center CP1 of the lead electrode LDE protruding from the flexible film FPCB and coordinates of the center CP2 of the pad part PAD exposed by the open part SOP of the first substrate SUB1. The center CP1 of the lead electrode LDE and the center CP2 of the pad part PAD corresponding to each other may be spaced apart from each other in the Y-axis direction.

In FIG. 11, the contact part CTP may be formed between the center CP1 of the lead electrode LDE and the center CP2 of the pad part PAD. The contact part CTP may be formed by printing metal paste including metal particles, a monomer, and a solvent on the open part SOP of the first substrate SUB1 using a silicon pad and then sintering the metal paste using a laser. The metal particles are in close contact with each other and agglomerate while the monomer is converted into a polymer due to heat generated by a laser in the sintering process, such that specific resistance of the contact part CTP may be reduced.

The sintered metal paste may cover one of a plurality of lead electrodes LDE inserted into one open part SOP and a pad part PAD corresponding to the one lead electrode LED. The plurality of contact parts CTP may be spaced apart from each other, and one contact part CTP may electrically connect one pad part PAD and one lead electrode LDE to each other. The plurality of contact parts CTP are individually formed without a separate laser patterning process, and thus, it is possible to prevent damage to the display panel 100, a short-circuit defect, and an over-sintering risk of the contact parts CTP due to laser patterning.

Accordingly, in the display device 10, by electrically connecting the lead electrode LDE and the pad part PAD to each other through the contact part CTP, the lead electrode LDE of the flexible film FPCB may be electrically connected to the pad part PAD without using ultrasonic bonding or thermocompression bonding. The contact part CTP may easily connect the lead electrode LDE and the pad part PAD to each other by complementing alignment between the lead electrode LDE and the pad part PAD. In addition, the display device 10 may reduce a manufacturing time and a manufacturing cost by simplifying manufacturing processes.

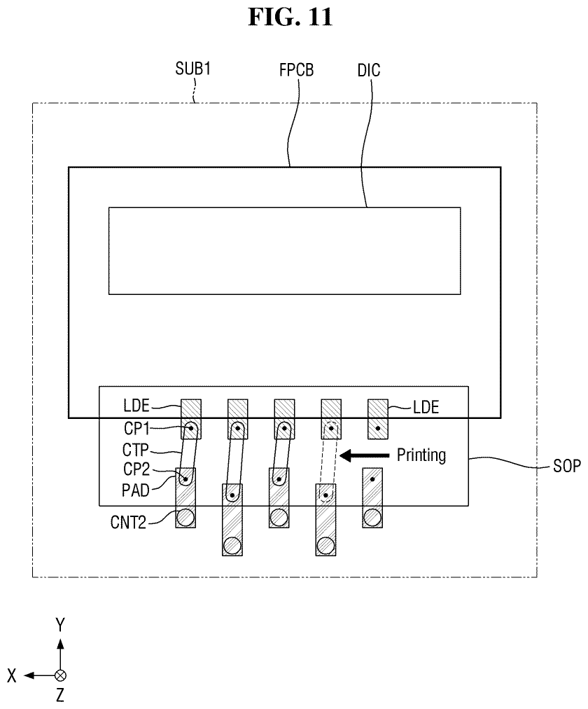

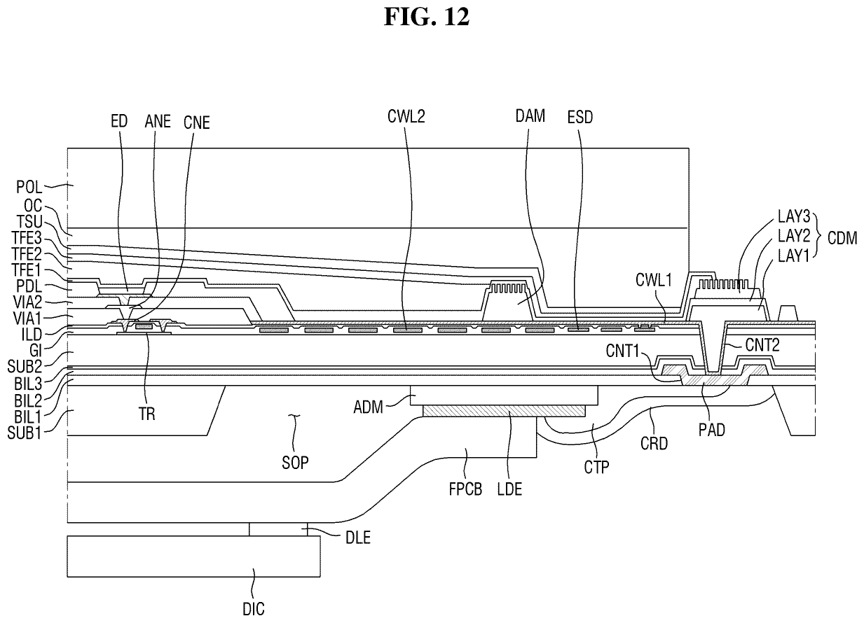

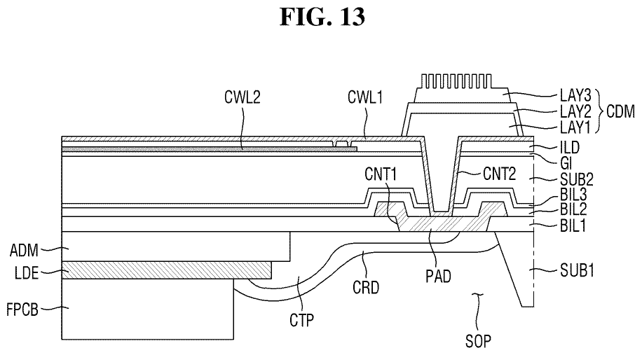

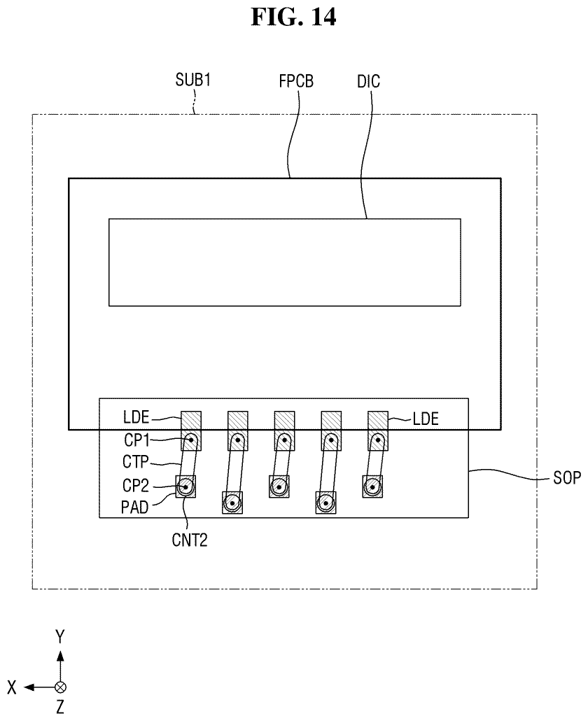

FIG. 12 is a cross-sectional view illustrating a portion of a display device according to another embodiment, FIG. 13 is a cross-sectional view illustrating a connection relationship between a pad part and a lead electrode in the display device according to another embodiment, and FIG. 14 is a bottom view illustrating the connection relationship between the pad part and the lead electrode in the display device according to another embodiment. A display device of FIGS. 12 to 14 is different from the display device of FIGS. 6 to 8 in a configuration of a pad part PAD, and the same configurations as the configurations described above will be briefly described or a description thereof will be omitted.

Referring to FIGS. 12 to 14, the pad part PAD may be disposed on the first barrier insulating layer BIL1 and inserted into a first contact hole CNT1 provided in the first barrier insulating layer BIL1. In manufacturing processes of the display device 10, a lower surface of the pad part PAD may be exposed through an open part SOP of the first substrate SUB1. The pad part PAD may electrically connect the flexible film FPCB and a first connection line CWL1 to each other. The pad part PAD may be spaced apart from a lead electrode LDE of the flexible film FPCB in plan view. The pad part PAD may be electrically connected to the lead electrode LDE of the flexible film FPCB through a contact part CTP.

The interlayer insulating layer ILD, the gate insulating layer GI, the second substrate SUB2, the third barrier insulating layer BIL3, and the second barrier insulating layer BIL2 may include a second contact hole CNT2. The second contact hole CNT2 may be etched from an upper surface of the interlayer insulating layer ILD to extend through the second barrier insulating layer BIL2. In a process of forming the second contact hole CNT2, an upper surface of the pad part PAD may be exposed. The second contact hole CNT2 may overlap the first contact hole CNT1. Accordingly, a portion of the first connection line CWL1 inserted into the second contact hole CNT2 and a portion of the lower surface of the pad part PAD exposed through the open part SOP may overlap each other.

The first connection line CWL1 may be disposed on the interlayer insulating layer ILD. The first connection line CWL1 may include the same material as the first source metal layer SDL1 of the display area DA and may be formed in the same process as the first source metal layer SDL1. A portion of the first connection line CWL1 may be inserted into the second contact hole CNT2 to be in contact with the upper surface of the pad part PAD. The other portion of the first connection line CWL1 may penetrate through the interlayer insulating layer ILD to be in contact with a second connection line CWL2. The first connection line CWL1 may electrically connect the pad part PAD and the second connection line CWL2 to each other. The first connection line CWL1 may supply a data voltage or a source voltage received from the pad part PAD to the second connection line CWL2.

The second connection line CWL2 may be disposed on the gate insulating layer GI. The second connection line CWL2 may include the same material as the gate layer GTL of the display area DA and may be formed in the same process as the gate layer GTL. The second connection line CWL2 may supply the data voltage received from the first connection line CWL1 to the data line DL The second connection line CWL2 may supply the source voltage received from the first connection line CWL1 to the power line VL. For example, the second connection line CWL2 may correspond to the signal line SL in FIG. 5 or may be electrically connected to the signal line SL.

In FIG. 14, the contact part CTP may electrically connect the lead electrode LDE and the pad part PAD to each other. The contact part CTP may correspond to a conductive line disposed between the lead electrode LDE and the pad part PAD spaced apart from each other. The contact part CTP may cover a lower surface of the lead electrode LDE protruding from the flexible film FPCB and the lower surface of the pad part PAD exposed through the open part SOP. The contact part CTP may cover the lower surface of the first barrier insulating layer BIL1 disposed between the lead electrode LDE and the pad part PAD. The contact part CTP may be a conductive line connecting the center CP1 of the lead electrode LDE protruding from the flexible film FPCB and the center CP2 of the pad part PAD inserted into the first contact hole CNT1 to each other. A portion of the contact part CTP may overlap the first and second contact holes CNT1 and CNT2. Each of a plurality of contact parts CTP may connect one of a plurality of lead electrodes LDE and a pad part PAD corresponding to the one lead electrode LDE to each other in a one-to-one manner. The contact part CTP may easily connect the lead electrode LED and the pad part PAD to each other by connecting the lead electrode LDE and the pad part PAD to each other in a one-to-one manner even when misalignment occurs in a process of aligning the lead electrode LDE and the pad part PAD with each other. The plurality of contact parts CTP are individually formed without a separate laser patterning process, and thus, it is possible to prevent damage to the display panel 100, a short-circuit defect, and an over-sintering risk of the contact parts CTP due to laser patterning.

The display device 10 may reduce a manufacturing time and a manufacturing cost by electrically connecting the lead electrode LDE and the pad part PAD to each other through the contact part CTP using the metal paste to simplify manufacturing processes without using ultrasonic bonding or thermocompression bonding.

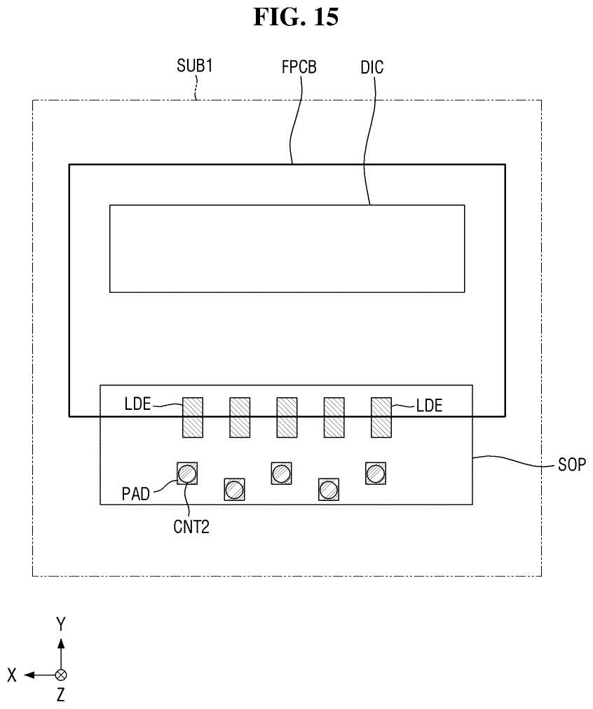

FIGS. 15 to 17 are bottom views illustrating manufacturing processes of the display device according to another embodiment.

In FIG. 15, the pad part PAD may be disposed on the first barrier insulating layer BIL1 and inserted into the first contact hole CNT1 provided in the first barrier insulating layer BIL1. The second contact hole CNT2 may overlap the first contact hole CNT1. Accordingly, a portion of the first connection line CWL1 inserted into the second contact hole CNT2 and a portion of the lower surface of the pad part PAD exposed through the open part SOP may overlap each other.

The flexible film FPCB may be disposed below the first substrate SUB1. One side of the flexible film FPCB may be inserted into the open part SOP of the first substrate SUB1. The lead electrode LDE of the flexible film FPCB may be disposed to be spaced apart from the pad part PAD in the Y-axis direction. The lead electrode LDE may protrude from one side of the flexible film FPCB, and a protruding portion of the lead electrode LDE may not overlap the flexible film FPCB. The lead electrode LDE may be attached to the lower surface of the first barrier insulating layer BIL1 through an adhesive member ADM. For example, the lead electrode LDE and the pad part PAD may be disposed on a virtual line extending in the Y-axis direction, but are not limited thereto.

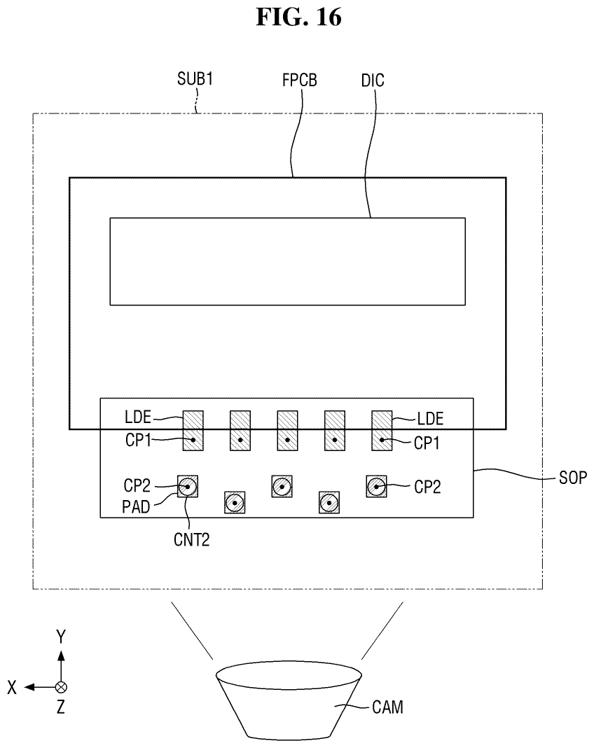

In FIG. 16, a camera CAM may scan coordinates of the center CP1 of the lead electrode LDE protruding from the flexible film FPCB and coordinates of the center CP2 of the pad part PAD exposed by the open part SOP of the first substrate SUB1. The center CP1 of the lead electrode LDE and the center CP2 of the pad part PAD corresponding to each other may be spaced apart from each other in the Y-axis direction.

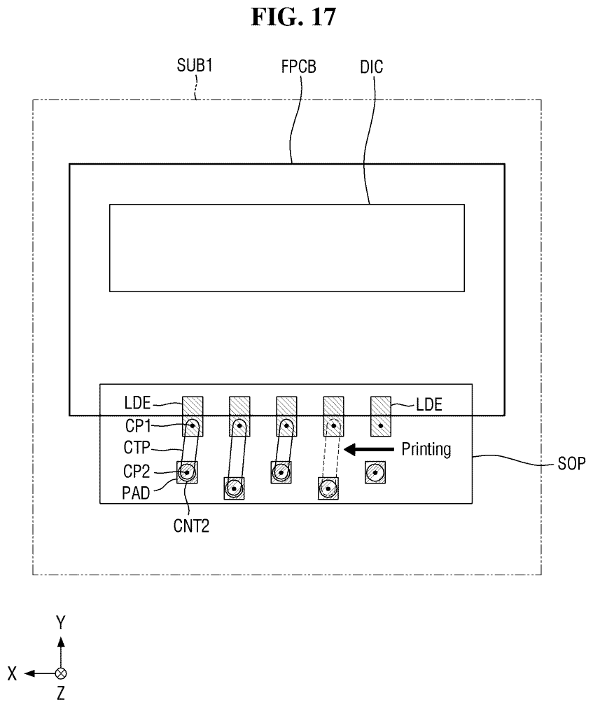

In FIG. 17, the contact part CTP may be formed between the center CP1 of the lead electrode LDE and the center CP2 of the pad part PAD. The contact part CTP may be formed by printing metal paste including metal particles, a monomer, and a solvent on the open part SOP of the first substrate SUB1 using a silicon pad and then sintering the metal paste using a laser. The metal particles are in close contact with each other and agglomerate while the monomer is converted into a polymer due to heat generated by a laser in the sintering process, such that specific resistance of the contact part CTP may be reduced.

The sintered metal paste may cover one of a plurality of lead electrodes LDE inserted into one open part SOP and a pad part PAD corresponding to the one lead electrode LED. The plurality of contact parts CTP may be spaced apart from each other, and one contact part CTP may electrically connect one pad part PAD and one lead electrode LDE to each other. The plurality of contact parts CTP are individually formed without a separate laser patterning process, and thus, it is possible to prevent damage to the display panel 100, a short-circuit defect, and an over-sintering risk of the contact parts CTP due to laser patterning.

Accordingly, in the display device 10, by electrically connecting the lead electrode LDE and the pad part PAD to each other through the contact part CTP, the lead electrode LDE of the flexible film FPCB may be electrically connected to the pad part PAD without using ultrasonic bonding or thermocompression bonding. The contact part CTP may easily connect the lead electrode LDE and the pad part PAD to each other by complementing alignment between the lead electrode LDE and the pad part PAD. In addition, the display device 10 may reduce a manufacturing time and a manufacturing cost by simplifying manufacturing processes.

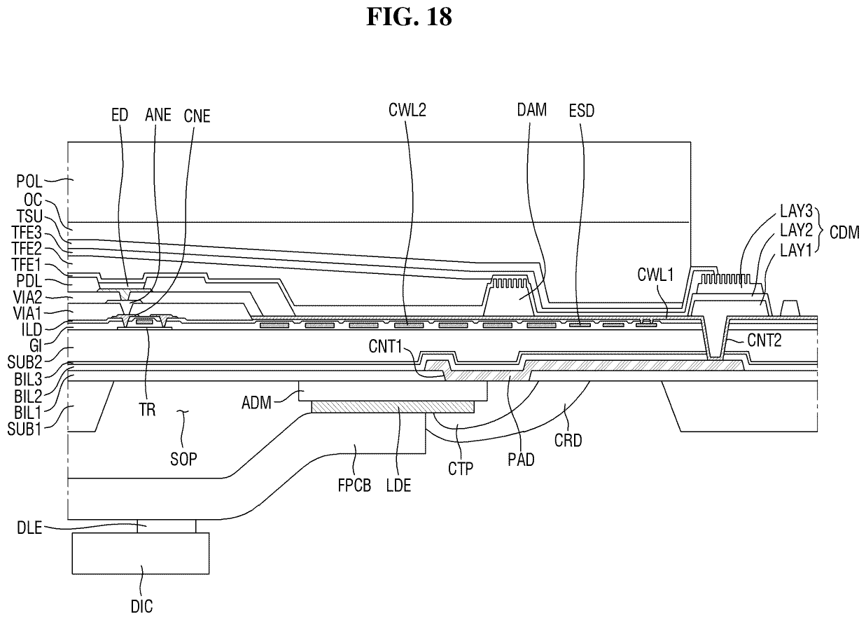

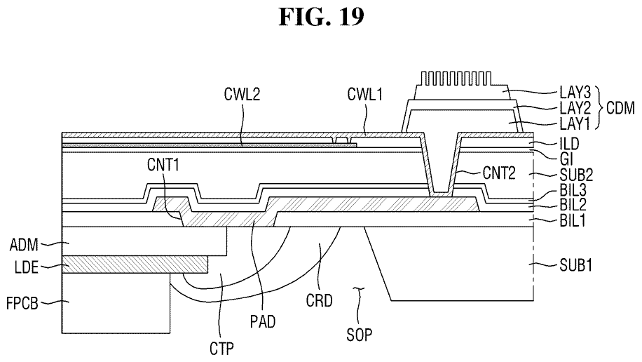

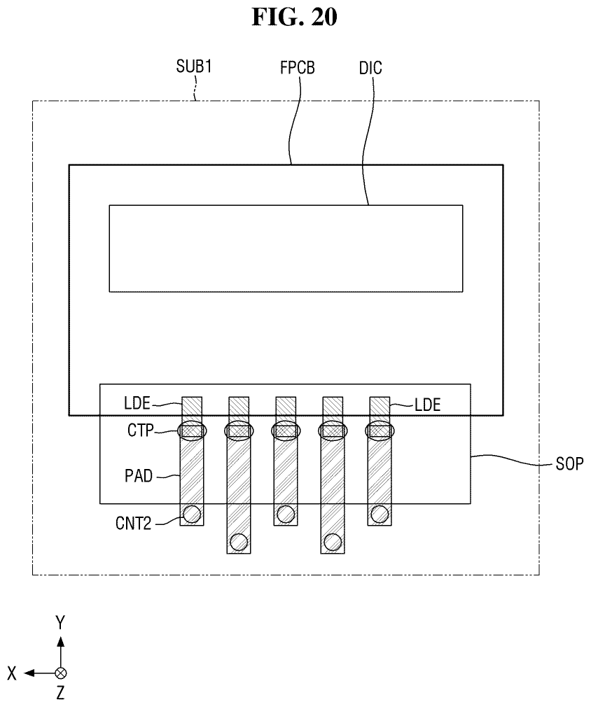

FIG. 18 is a cross-sectional view illustrating a portion of a display device according to another embodiment, and FIG. 19 is a cross-sectional view illustrating a connection relationship between a pad part and a lead electrode in the display device according to another embodiment. FIG. 20 is a bottom view illustrating the connection relationship between the pad part and the lead electrode in the display device according to another embodiment. A display device of FIGS. 18 to 20 is different from the display device of FIGS. 6 to 8 in configurations of a lead electrode LDE and a contact part CTP, and the same configurations as the configurations described above will be briefly described or a description thereof will be omitted.

Referring to FIGS. 18 to 20, the pad part PAD may be disposed on the first barrier insulating layer BIL1 and inserted into a first contact hole CNT1 provided in the first barrier insulating layer BIL1. In manufacturing processes of the display device 10, a lower surface of the pad part PAD may be exposed through an open part SOP of the first substrate SUB1. The pad part PAD may electrically connect the flexible film FPCB and a first connection line CWL1 to each other. The pad part PAD may overlap a portion of the lead electrode LDE in plan view. The pad part PAD may be electrically connected to the lead electrode LDE of the flexible film FPCB through a contact part CTP.

The interlayer insulating layer ILD, the gate insulating layer GI, the second substrate SUB2, the third barrier insulating layer BIL3, and the second barrier insulating layer BIL2 may include a second contact hole CNT2. The second contact hole CNT2 may be etched from an upper surface of the interlayer insulating layer ILD to extend through the second barrier insulating layer BIL2. In a process of forming the second contact hole CNT2, an upper surface of the pad part PAD may be exposed. The first and second contact holes CNT1 and CNT2 may be spaced apart from each other in plan view.

The first connection line CWL1 may be disposed on the interlayer insulating layer ILD. The first connection line CWL1 may include the same material as the first source metal layer SDL1 of the display area DA and may be formed in the same process as the first source metal layer SDL1. A portion of the first connection line CWL1 may be inserted into the second contact hole CNT2 to be in contact with the upper surface of the pad part PAD. The other portion of the first connection line CWL1 may penetrate through the interlayer insulating layer ILD to be in contact with a second connection line CWL2. The first connection line CWL1 may electrically connect the pad part PAD and the second connection line CWL2 to each other. The first connection line CWL1 may supply a data voltage or a source voltage received from the pad part PAD to the second connection line CWL2.

The second connection line CWL2 may be disposed on the gate insulating layer GI. The second connection line CWL2 may include the same material as the gate layer GTL of the display area DA and may be formed in the same process as the gate layer GTL. The second connection line CWL2 may supply the data voltage received from the first connection line CWL1 to the data line DL The second connection line CWL2 may supply the source voltage received from the first connection line CWL1 to the power line VL. For example, the second connection line CWL2 may correspond to the signal line SL in FIG. 5 or may be electrically connected to the signal line SL.

In FIG. 20, the contact part CTP may cover a lower surface of the lead electrode LDE protruding from the flexible film FPCB and the lower surface of the pad part PAD exposed through the open part SOP. The contact part CTP may electrically connect the lead electrode LDE and the pad part PAD to each other. The contact part CTP may overlap the first contact hole CNT1 and may not overlap the second contact hole CNT2. Each of a plurality of contact parts CTP may connect one of a plurality of lead electrodes LDE and a pad part PAD corresponding to the one lead electrode LDE to each other in a one-to-one manner. The plurality of contact parts CTP are individually formed without a separate laser patterning process, and thus, it is possible to prevent damage to the display panel 100, a short-circuit defect, and an over-sintering risk of the contact parts CTP due to laser patterning.

The display device 10 may reduce a manufacturing time and a manufacturing cost by electrically connecting the lead electrode LDE and the pad part PAD to each other through the contact part CTP using the metal paste to simplify manufacturing processes without using ultrasonic bonding or thermocompression bonding.

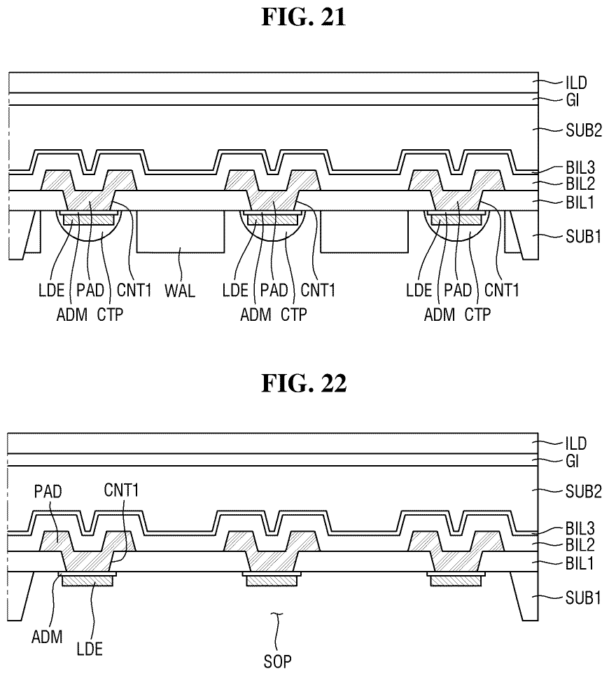

FIG. 21 is a cross-sectional view illustrating partition walls in the display device according to another embodiment.

Referring to FIG. 21, partition walls WAL may be inserted into the open part SOP of the first substrate SUB1 and disposed between adjacent pad parts PAD. The partition walls WAL may be disposed between adjacent contact parts CTP on the lower surface of the first barrier insulating layer BIL1. The contact parts CTP may connect the lead electrodes LDE and the pad parts PAD to each other in a one-to-one manner between adjacent partition walls WAL. The partition walls WAL may prevent adjacent contact parts CTP from being short-circuited to each other in a process of forming the contact parts CTP. The partition wall WAL may include an organic film made of an acrylic resin, an epoxy resin, a phenolic resin, a polyamide resin, a polyimide resin, or the like. A thickness of the partition wall WAL may be greater than a thickness of the contact part CTP, but is not limited thereto.

FIGS. 22 to 25 are cross-sectional views illustrating manufacturing processes of the display device according to another embodiment.

In FIG. 22, the open part SOP may be formed by etching one surface of the first substrate SUB1. At least one of a wet etching process, a dry etching process, a plasma etching process, and a laser etching process may be performed on one surface of the first substrate SUB1. The open part SOP may be provided in the first substrate SUB1 to expose the pad parts PAD. One open part SOP may expose a plurality of pad parts PAD, but is not limited thereto.

The lead electrodes LDE may be inserted into the open part SOP of the first substrate SUB1. The lead electrodes LDE may be attached to the lower surfaces of the pad parts PAD through adhesive members ADM.

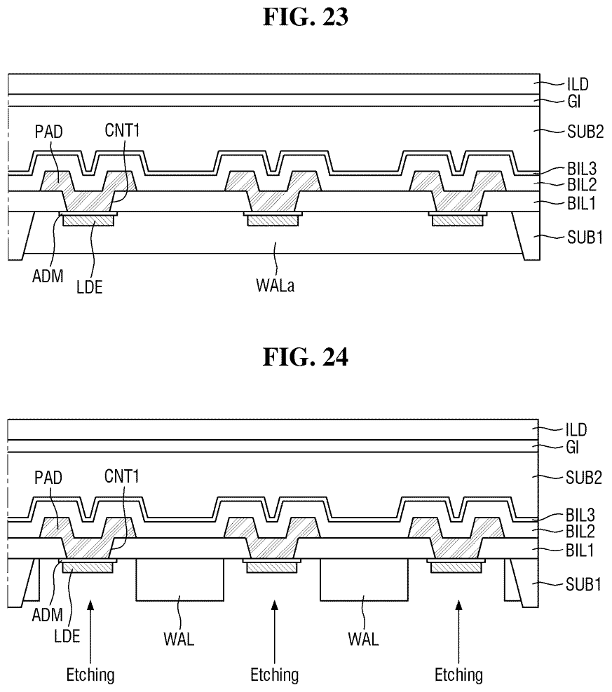

In FIG. 23, an organic material WALa may be inserted into the open part SOP of the first substrate SUB1 to cover the pad parts PAD and the lower surfaces of the lead electrodes LDE. The organic material WALa may include at least one of an acrylic resin, an epoxy resin, a phenolic resin, a polyamide resin, and a polyimide resin.

In FIG. 24, a plurality of partition walls WAL may be formed by etching the organic material WALa. Portions of the organic material WALa overlapping the lead electrodes LDE may be etched to expose the lead electrodes LDE and the pad parts PAD. For example, the organic material WALa may be etched through at least one of a wet etching process, a dry etching process, a plasma etching process, and a laser etching process.

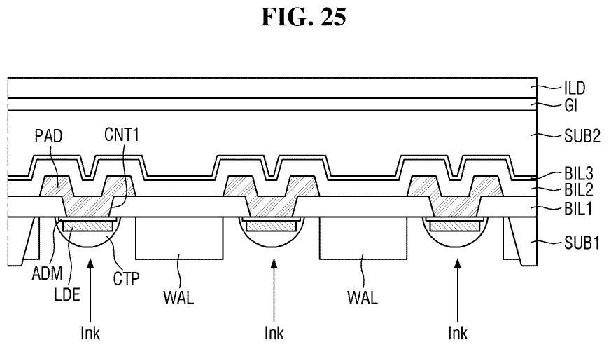

In FIG. 25, the contact parts CTP may cover the lower surfaces of the lead electrodes LDE and the lower surfaces of the pad parts PAD. The contact parts CTP may be formed between adjacent partition walls WAL. The lead electrodes LDE may be electrically connected to the pad parts PAD through the contact parts CTP. It has been illustrated in FIG. 25 that the contact parts CTP and the pad parts PAD are not in direct contact with each other, but the contact parts CTP and the pad parts PAD may be in direct contact with each other in cross-sectional views in other directions as in FIGS. 18 and 19.

Conductive ink Ink may be applied onto the lead electrodes LDE and the pad parts PAD. The conductive ink Ink may include nanoparticles and a polymer. The contact parts CTP may be formed by low temperature sintering of the conductive ink.

The sintered conductive ink may cover one of a plurality of lead electrodes LDE inserted into one open part SOP and a pad part PAD corresponding to the one lead electrode LED. The plurality of contact parts CTP may be spaced apart from each other, and one contact part CTP may electrically connect one pad part PAD and one lead electrode LDE to each other. The plurality of contact parts CTP are individually formed without a separate laser patterning process, and thus, it is possible to prevent damage to the display panel 100, a short-circuit defect, and an over-sintering risk of the contact parts CTP due to laser patterning.

Accordingly, in the display device 10, by electrically connecting the lead electrode LDE and the pad part PAD to each other through the contact part CTP, the lead electrode LDE of the flexible film FPCB may be electrically connected to the pad part PAD without using ultrasonic bonding or thermocompression bonding. In addition, the display device 10 may reduce a manufacturing time and a manufacturing cost by simplifying manufacturing processes.

While the present disclosure has been described with reference to embodiments thereof, it will be apparent to those of ordinary skill in the art that various changes and modifications may be made thereto without departing from the scope and spirit of the present disclosure as set forth in the following claims.

What is claimed is:

1. A display device comprising:
a first substrate including an open part;
a first barrier insulating layer disposed on the first substrate and including a first contact hole;
a pad part disposed on the first barrier insulating layer and inserted into the first contact hole;
a second substrate disposed on the pad part;
a first connection line disposed on the second substrate and connected to the pad part;
a flexible film partially inserted into the open part of the first substrate and including a lead electrode spaced apart from the pad part in a plan view; and
a contact part electrically connecting the pad part and the lead electrode to each other.

2. The display device of claim 1, wherein the contact part covers a lower surface of the lead electrode and a lower surface of the pad part.

3. The display device of claim 1, wherein the contact part covers a lower surface of the first barrier insulating layer disposed between the lead electrode and the pad part.

4. The display device of claim 1, wherein the contact part corresponds to a conductive line connecting a center of the lead electrode protruding from the flexible film and a center of the pad part inserted into the first contact hole to each other.

5. The display device of claim 1, wherein the second substrate includes a second contact hole spaced apart from the first contact hole in the plan view, and the first connection line is inserted into the second contact hole to be connected to the pad part.

6. The display device of claim 1, wherein the second substrate includes a second contact hole overlapping the first contact hole, and the first connection line is inserted into the second contact hole to be connected to the pad part.

7. The display device of claim 1, further comprising:
a gate insulating layer disposed on the second substrate;
a second connection line disposed on the gate insulating layer and connected to the first connection line; and
an interlayer insulating layer disposed at a layer between the second connection line and the first connection line.

8. The display device of claim 7, further comprising:
a semiconductor region of a transistor disposed on the second substrate;
a gate electrode of the transistor disposed on the gate insulating layer; and
a connection electrode disposed on the interlayer insulating layer and electrically connected to the transistor,
wherein the first connection line includes the same material as the connection electrode and is formed in the same process as the connection electrode, and
the second connection line includes the same material as the gate electrode of the transistor and is formed in the same process as the gate electrode.

9. A display device comprising:
a first substrate including an open part;
a first barrier insulating layer disposed on the first substrate and including a plurality of first contact holes;
a plurality of pad parts disposed on the first barrier insulating layer and inserted into the plurality of first contact holes, respectively;
a second substrate disposed on the plurality of pad parts;
a plurality of first connection lines disposed on the second substrate and connected to the plurality of pad parts, respectively;
a flexible film partially inserted into the open part of the first substrate and including a plurality of lead electrodes;
a plurality of partition walls disposed between adjacent pad parts of the plurality of pad parts on a lower surface of the first barrier insulating layer; and
contact parts connecting the pad parts and the lead electrodes to each other in a one-to-one manner between adjacent partition walls of the plurality of partition walls.

10. The display device of claim 9, wherein a lead electrode of the lead electrodes is attached to a lower surface of a pad part of the pad parts through an adhesive member, and a contact part of the contact parts covers a lower surface of the lead electrode and the lower surface of the pad part.

11. The display device of claim 9, wherein the partition wall includes an organic film made of an acrylic resin, an epoxy resin, a phenolic resin, a polyamide resin, or a polyimide resin.

12. A method of manufacturing a display device, comprising:
providing a first substrate;
forming a first barrier insulating layer on the first substrate, the first barrier insulating layer including a first contact hole;
forming a pad part disposed on the first barrier insulating layer and inserted into the first contact hole;
forming a second substrate on the pad part, the second substrate including a second contact hole;
forming a first connection line disposed on the second substrate and inserted into the second contact hole to be connected to the pad part;
forming an open part by etching a lower surface of the first substrate, the open part exposing the pad part and a lower surface of the first barrier insulating layer;
disposing a lead electrode of a flexible film on the lower surface of the first barrier insulating layer so as to be spaced apart from the pad part in a plan view; and
forming a contact part electrically connecting the pad part and the lead electrode to each other.

13. The method of manufacturing a display device of claim 12, wherein the forming of the contact part comprises scanning coordinates of a center of the lead electrode protruding from the flexible film and coordinates of a center of the pad part exposed by the open part.

14. The method of manufacturing a display device of claim 13, wherein the forming of the contact part further comprises printing and sintering metal paste between the center of the lead electrode and the center of the pad part.

15. The method of manufacturing a display device of claim 12, wherein the forming of the second substrate comprises forming the second contact hole so as to be spaced apart from the first contact hole in the plan view.

16. The method of manufacturing a display device of claim 12, wherein the forming of the second substrate comprises forming the second contact hole so as to overlap the first contact hole.

17. A method of manufacturing a display device, comprising:
providing a first substrate;
forming a first barrier insulating layer on the first substrate, the first barrier insulating layer including a plurality of first contact holes;
forming a plurality of pad parts disposed on the first barrier insulating layer and inserted into the plurality of first contact holes, respectively;
forming a second substrate on the plurality of pad parts, the second substrate including a plurality of second contact holes;
forming a plurality of first connection lines disposed on the second substrate and inserted into the plurality of second contact holes, respectively, to be connected to the plurality of pad parts, respectively;
forming an open part by etching a lower surface of the first substrate, the open part exposing the plurality of pad parts and a lower surface of the first barrier insulating layer;
disposing lead electrodes of a flexible film on lower surfaces of the pad parts;
forming a plurality of partition walls disposed between adjacent pad parts of the plurality of pad parts on the lower surface of the first barrier insulating layer; and
forming contact parts connecting the pad parts and the lead electrodes to each other in a one-to-one manner.

18. The method of manufacturing a display device of claim 17, wherein the forming of the plurality of partition walls comprises covering the pad parts and the lead electrodes with an organic material.

19. The method of manufacturing a display device of claim 18, wherein the forming of the plurality of partition walls further comprises exposing the lead electrodes and the pad parts by etching portions of the organic material overlapping the lead electrodes.

20. The method of manufacturing a display device of claim 17, wherein the forming of the contact parts comprises applying conductive ink between the partition walls and then sintering the conductive ink at a low temperature.
